(19) United States
(12) Patent Application Publication
(10) Pub. No.: US 2025/0201713 A1
(43) Pub. Date: Jun. 19, 2025

(54) SEMICONDUCTOR DEVICE

(71) Applicant: Sumitomo Electric Device Innovations, Inc., Yokohama-shi (JP)

(72) Inventors: Masato KITSUKAWA, Yokohama-shi (JP); Takuma MORI, Yokohama-shi (JP); Fumio YAMADA, Yokohama-shi (JP)

(73) Assignee: Sumitomo Electric Device Innovations, Inc., Yokohama-shi (JP)

(21) Appl. No.: 19/067,530

(22) Filed: Feb. 28, 2025

Related U.S. Application Data
(63) Continuation-in-part of application No. 18/825,197, filed on Sep. 5, 2024.

(30) Foreign Application Priority Data
Sep. 6, 2023 (JP) 2023-144685

(51) Int. Cl. H01L 23/528; H01L 23/522; H10D 84/83

(52) U.S. Cl. CPC H01L 23/5286; H01L 23/5226; H10D 84/83

(57) ABSTRACT

A semiconductor device includes a substrate having main and back surfaces, and a first transistor and a second transistor. A first end of a via hole which penetrates the substrate and is farther from the second transistor is farther from the second transistor than a second end of an active region which is farther from the second transistor in a region where a first gate electrode of the first transistor is disposed, as viewed from a first direction.

### CROSS REFERENCE TO RELATED APPLICATION

This application is a continuation-in-part application claiming priority under 35 U.S.C. § 120 to U.S. patent application Ser. No. 18/825,197, filed on Sep. 5, 2024, which claims priority based on Japanese Patent Application No. 2023-144685, filed Sep. 6, 2023, the entire disclosures of which are hereby incorporated by reference herein.

### FIELD

A certain aspect of the embodiments is related to a semiconductor device.

### BACKGROUND

In a field effect transistor (FET) having a finger-shaped source electrode, a finger-shaped gate electrode, and a finger-shaped drain electrode, it is known that a plurality of unit FETs having a source electrode, a gate electrode, and a drain electrode are arranged in the extending direction of the electrodes (for example, Patent Documents 1: Japanese Laid-Open Patent Publication No. 2002/299351, Patent Document 2: U.S. Patent Application Publication No. 2017/0271329).

### SUMMARY

A semiconductor device according to the present disclosure includes a substrate having a main surface and a back surface facing the main surface, a first transistor provided on the main surface of an active region provided on the substrate, the first transistor having a first source electrode, a first drain electrode, and a first gate electrode interposed between the first source electrode and the first drain electrode in a first direction, a second transistor provided on the main surface, the second transistor having a second source electrode disposed in the first source electrode and electrically connected to the first source electrode when viewed from a second direction intersecting the first direction, a second drain electrode electrically connected to the first drain electrode, and a second gate electrode interposed between the second source electrode and the second drain electrode in the first direction, a first gate wiring provided on the main surface, disposed in the first source electrode when viewed from the second direction, and electrically connected to the first gate electrode, the second source electrode being interposed between the first gate wiring and the second gate electrode, and a back metal layer provided on the back surface and electrically connected to the first source electrode through a first via hole penetrating the substrate, wherein a first end of the first via hole which is farther from the second transistor is farther from the second transistor than a second end of the active region which is farther from the second transistor in a region where the first gate electrode is disposed, as viewed from the first direction.

### BRIEF DESCRIPTION OF THE DRAWINGS

FIG. 1 is a plan view of a semiconductor device according to a first embodiment.

FIG. 2 is a cross-sectional view taken along a line A-A in FIG. 1.

FIG. 3 is a cross-sectional view taken along a line B-B in FIG. 1.

FIG. 4 is a cross-sectional view taken along a line C-C in FIG. 1.

FIG. 5 is a cross-sectional view taken along a line D-D in FIG. 1.

FIG. 6 is a plan view of a semiconductor device according to a first comparative example.

FIG. 7 is an enlarged plan view of a semiconductor device according to a first embodiment.

FIG. 8 is a plan view of a semiconductor device according to a first modification of the first embodiment.

FIG. 9 is a plan view of a semiconductor device according to a second embodiment.

FIG. 10 is an enlarged plan view of a semiconductor device according to the second embodiment.

FIG. 11 is a plan view of a semiconductor device according to a first modification of the second embodiment.

FIG. 12 is a plan view of a semiconductor device according to a third embodiment.

FIG. 13 is a plan view of a semiconductor device according to a modification of the third embodiment.

### DETAILED DESCRIPTION

In Patent document 1, the width of the gate electrode of the unit FET can be shortened by arranging a plurality of the unit FETs in the extending direction of the electrode. Therefore, the gate resistance can be suppressed. However, since the source electrode and the gate wiring overlap each other in plan view, the gate-source parasitic capacitance increases, and the characteristics deteriorate.

The present disclosure has been made in view of the above problems, and an object thereof is to suppress deterioration of characteristics.

### Description of Embodiments of the Present Disclosure

First, the contents of the embodiments of the present disclosure are listed and explained.

(1) A semiconductor device according to the present disclosure includes a substrate having a main surface and a back surface facing the main surface, a first transistor provided on the main surface of an active region provided on the substrate, the first transistor having a first source electrode, a first drain electrode, and a first gate electrode interposed between the first source electrode and the first drain electrode in a first direction, a second transistor provided on the main surface, the second transistor having a second source electrode disposed in the first source electrode and electrically connected to the first source electrode when viewed from a second direction intersecting the first direction, a second drain electrode electrically connected to the first drain electrode, and a second gate electrode interposed between the second source electrode and the second drain electrode in the first direction, a first gate wiring provided on the main surface, disposed in the first source electrode when viewed from the second direction, and electrically connected to the first gate electrode, the second source electrode being interposed between the first gate wiring and the second gate electrode, and a back metal layer provided on the back surface and electrically connected to the first source electrode through a first via hole penetrating the substrate, wherein a first end of the first via hole which is farther from the second transistor is farther from the second transistor than a second end of the active region which is farther from the second transistor in a region where the first gate electrode is disposed, as viewed from the first direction. This makes it possible to suppress a source inductance and suppress the deterioration of the characteristics.

(2) The first via hole may be formed in the first source electrode when viewed in a thickness direction of the substrate. This increases a contact area between the via hole and the first source electrode, and can reduce the source inductance and a source resistance.

(3) The semiconductor device may further include a drain bus bar provided on the main surface, the first transistor being interposed between the second transistor and the drain bus bar, and a drain wiring connecting the first drain electrode and the second drain electrode to the drain bus bar, wherein a distance between the first source electrode and the drain wiring at a third end of the first source electrode farther from the second transistor when viewed from the first direction is larger than a distance between the first source electrode and the drain wiring at the second end. This makes it possible to suppress a drain-source parasitic capacitance.

(4) The third end of the first source electrode may be provided on an inactive region provided on the substrate. This makes it possible to suppress the drain-source parasitic capacitance.

(5) A distance between the first source electrode and the drain wiring may increase from the second end toward the third end. This makes it possible to suppress the drain-source parasitic capacitance.

(6) A gate width of the first transistor may be 0.9 times or more and 1.1 times or less of a gate width of the second transistor. This makes it possible to make the characteristics of the transistors uniform.

(7) The first gate electrode and the second gate electrode may be separated from each other between the first transistor and the second transistor. This makes it possible to suppress deterioration of the characteristics.

(8) The first gate electrode and the second gate electrode may be connected between the first transistor and the second transistor. This can reduce a gate resistance.

(9) The semiconductor device may further include a third transistor provided on the main surface, having the first source electrode, a third drain electrode and a third gate electrode, the first source electrode being interposed between the first source electrode and the first gate electrode, the third gate electrode being interposed between the first source electrode and the third drain electrode in the first direction, and a fourth transistor provided on the main surface, having a third source electrode, a fourth drain electrode and a fourth gate electrode, the first gate wiring being interposed between the second source electrode and the third source electrode, the third source electrode being disposed in the first source electrode viewed from the second direction, the third source electrode being interposed between the first gate wiring and the fourth drain electrode, the second gate electrode being interposed between the third source electrode and the fourth drain electrode in the first direction. This allows the transistors to be arranged in the first and second directions.

(10) The semiconductor device may further include a source wiring provided on the main surface and electrically connecting the first source electrode and the second source electrode, and a second gate wiring provided on the main surface and electrically connecting the first gate wiring and the first gate electrode. This allows the first gate electrode and the gate wiring to be electrically connected.

(11) The semiconductor device according to claim 1 may further include a gate bus bar provided on the main surface and connected to the second gate electrode and the first gate wiring, and a drain bus bar provided on the main surface and electrically connected to the first drain electrode and the second drain electrode, the first transistor and the second transistor being interposed between the gate bus bar and the drain bus bar. Thus, a gate potential can be supplied from the gate bus bar to the gate electrode, and a drain potential can be supplied from the drain bus bar to the drain electrode.

(12) The semiconductor device according to claim 9 may further include a source connection wiring provided on the main surface at an opposite side of the second transistor and the fourth transistor with respect to the first transistor and the third transistor. The source connection wiring may electrically connect the second source electrode of the second transistor to the third source electrode of the fourth transistor. The source connection wiring may be electrically connected to the back metal layer through a second via hole penetrating the substrate. A distance between the source connection wiring and the first gate wiring may increase in accordance with a position farther from the second transistor and the fourth transistor in the second direction. A gate-source parasitic capacitance can be suppressed.

A description will be given, with reference to the accompanying drawings, of embodiments of semiconductor devices according to the present disclosure. It is to be understood that the present disclosure is not limited to these embodiments, but is intended to be set forth by the appended claims and to include all modifications within the meaning and scope of the equivalents of the appended claims.

### FIRST EMBODIMENT

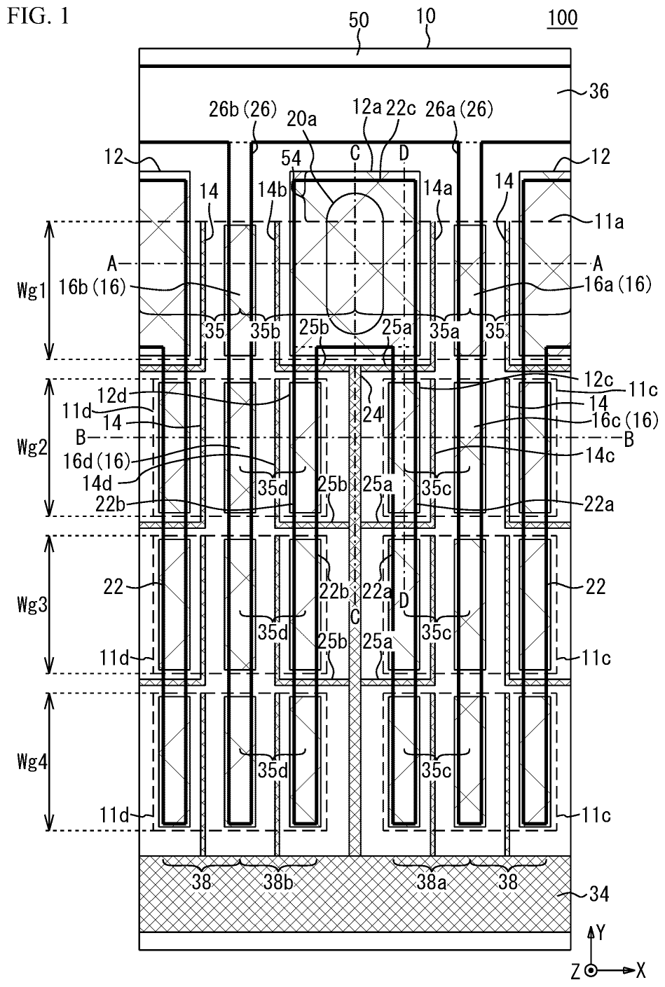

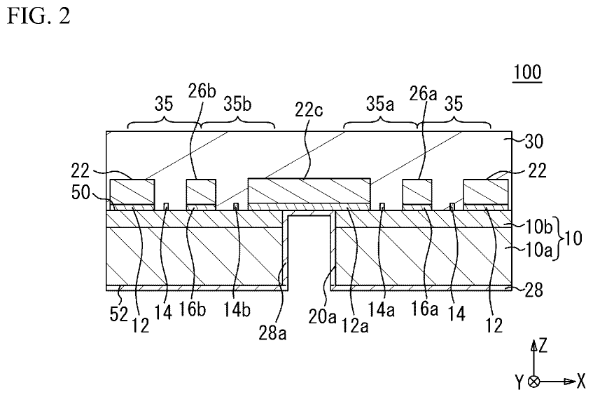

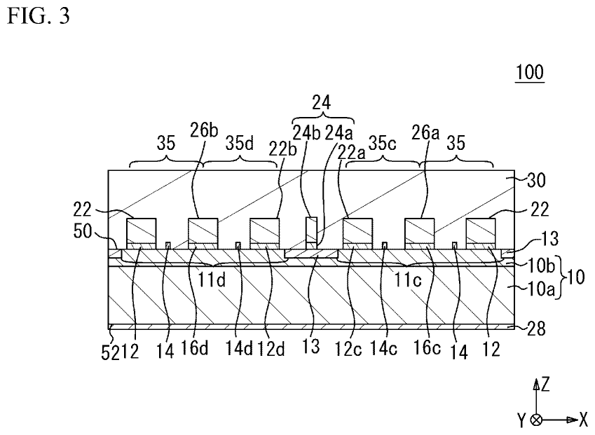

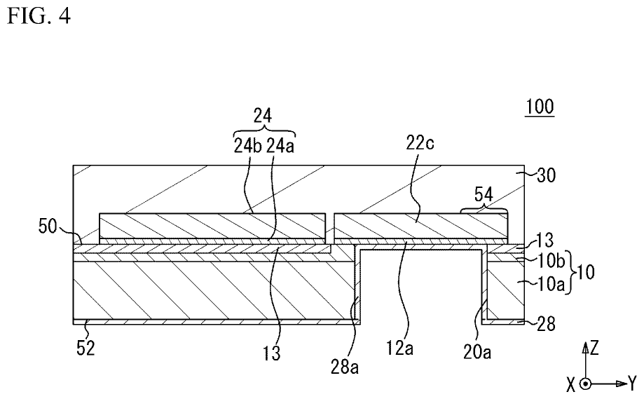

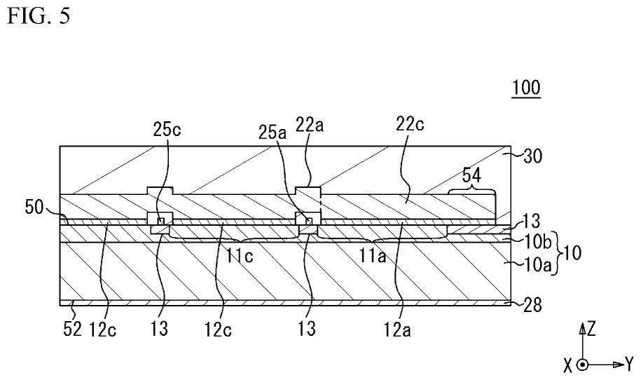

A semiconductor device used in an amplifier for amplifying a high frequency signal of, for example, 0.5 GHz to 10 GHz in a base station of mobile communication will be described as an example. FIG. 1 is a plan view of a semiconductor device according to a first embodiment. FIGS. 2 to 5 are cross-sectional views taken along lines A-A, B-B, C-C, and D-D in FIG. 1, respectively. The thickness direction of a substrate 10 is defined as a Z direction, the extending direction of a finger-shaped source electrode 12, a gate electrode 14 and a drain electrode 16 is defined as a Y direction (a second direction intersecting with the first direction), and the arrangement direction of the source electrode 12, gate electrode 14 and drain electrode 16 is defined as an X direction (a first direction).

In the plan view of FIG. 1 and the like, it is difficult to see the source electrode 12 and the drain electrode 16 overlap with a source wiring 22 and a drain wiring 26. Therefore, thick broken lines illustrating only the outer peripheries of the source wiring 22 and the drain wiring 26 are illustrated inside the source electrode 12 and the drain electrode 16 in a perspective view of the source wiring 22 and the drain wiring 26.

In each figure, the active regions 11, the source electrodes 12, the gate electrodes 14, the drain electrodes 16, the source wirings 22, the drain wirings 26, and transistors 35 (unit FETs) indicate general elements, and active regions 11a, 11c, 11d, source electrodes 12a, 12c, 12d, gate electrodes 14a, 14b, 14c and 14d, drain electrodes 16a, 16b, 16c and 16d, source wiring 22a, 22b and 22c, drain wiring 26a and 26b, and transistors 35a, 35b, 35c and 35d indicate specific elements included in the general elements. In the following, the transistors 35a to 35d will be described by using the active regions 11a, 11c, 11d, the source electrodes 12a, 12c, 12d, the gate electrodes 14a to 14d, the drain electrodes 16a to 16d, the source wirings 22a to 22c, and the drain wirings 26a and 26b.

As illustrated in FIGS. 1 to 5, in the semiconductor device 100 of the first embodiment, the substrate 10 has a main surface 50 and a back surface 52 facing the main surface 50. A plurality of transistors 35a to 35d are provided on the main surface of the substrate 10. Transistors 35, 35a to 35d arranged in the Y direction form transistor groups 38, 38a and 38b. In the Y direction, a drain bus bar 36 and a gate bus bar 34 are provided on the main surface 50, and the transistor groups 38, 38a and 38b are interposed therebetween.

Transistors 35 closest to drain bus bar 36 are transistors 35a and 35b. Transistors 35 closer to the gate bus bar 34 than transistors 35a and 35b are transistors 35c and 35d. The transistor group 38a includes one transistor 35a and three transistors 35c. The transistor group 38b includes one transistor 35b and three transistors 35d. The number of transistors 35c is one or more, and the number of transistors 35d is one or more.

The substrate 10 includes a substrate 10a and a semiconductor layer 10b provided on the substrate 10a. In the XY plane parallel to the X direction and the Y direction, a region where the semiconductor layer 10b is inactivated by ion implantation or the like is an inactive region 13, and non-inactivated regions (regions where a current flows when the transistor is in the ON state) are active regions 11a, 11c, and 11d. The active region 11a extends in the X direction. The active regions 11c and 11d are arranged in the X direction. The three active regions 11c are arranged in the Y direction, and the three active regions 11d are arranged in the Y direction. The transistors 35a and 35b are provided in the active region 11a. The transistors 35c and 35d are provided in the active regions 11c and 11d, respectively.

The transistor 35a (first transistor) includes the source electrode 12a (first source electrode), the gate electrode 14a (first gate electrode), and the drain electrode 16a (first drain electrode). The gate electrode 14a is interposed between the source electrode 12a and the drain electrode 16a in the X direction. The source electrode 12a, the gate electrode 14a, and the drain electrode 16a are arranged in order in the + direction of the X direction.

The transistor 35b (third transistor) includes the source electrode 12a, a gate electrode 14b (third gate electrode), and a drain electrode 16b (third drain electrode). The source electrode 12a is interposed between the drain electrode 16b and the gate electrode 14a. The gate electrode 14b is interposed between the source electrode 12a and the drain electrode 16b in the X direction. The source electrode 12a, the gate electrode 14b and the drain electrode 16b are arranged in order in the-direction of the X direction. The transistors 35a and 35b share the source electrode 12a.

The transistor 35c (second transistor) includes the source electrode 12c (second source electrode), the gate electrode 14c (second gate electrode), and the drain electrode 16c (second drain electrode). The gate electrode 14c is interposed between the source electrode 12c and the drain electrode 16c in the X direction. The source electrode 12c is disposed in the source electrode 12a when viewed from the Y direction. That is, the source electrode 12c is not disposed outside the source electrode 12a when viewed from the Y direction. The plurality of source electrodes 12c are overlapped with each other when viewed from the Y direction. The plurality of drain electrodes 16c are overlapped with each other when viewed from the Y direction. The source electrode 12c, the gate electrode 14c, and the drain electrode 16c are arranged in order in the + direction of the X direction.

The transistor 35d (fourth transistor) includes the source electrode 12d (third source electrode), the gate electrode 14d (fourth gate electrode), and the drain electrode 16d (fourth drain electrode). The source electrode 12d is disposed in the source electrode 12a, with a gate wiring 24 interposed between the source electrode 12d and the source electrode 12c, as viewed in the Y direction. That is, the source electrode 12d is not disposed outside the source electrode 12a when viewed from the Y direction. The plurality of source electrodes 12d are overlapped with each other when viewed from the Y direction. The plurality of drain electrodes 16d are overlapped with each other when viewed from the Y direction. The gate electrode 14d is interposed between the source electrode 12d and the drain electrode 16d in the X direction. The source electrode 12d, the gate electrode 14d and the drain electrode 16d are arranged in order in the − direction of the X direction.

The source wiring 22c is provided on the source electrode 12a in contact with the source electrode 12a. When viewed in the X direction, the + end of the source electrode 12a in the Y direction is located farther from the transistors 35c and 35d than the + end of the gate electrodes 14a and 14b in the Y direction. A portion 54 of the source electrode 12a that is further from the transistors 35c and 35d than the gate electrodes 14a and 14b when viewed in the X direction is provided on the inactive region 13.

The source wiring 22a (first source wiring) is disposed in contact with the source electrode 12c. The source wiring 22a extends in the Y direction, electrically connects the plurality of source electrodes 12c to each other, and electrically connects the plurality of source electrodes 12c and the source wiring 22c. The source wiring 22b (second source wiring) is provided in contact with the source electrode 12d. The source wiring 22b extends in the Y direction, electrically connects the plurality of source electrodes 12d to each other, and electrically connects the plurality of source electrodes 12d and the source wiring 22c.

The drain wiring 26a is provided in contact with the drain electrodes 16a and 16c. The drain wiring 26a extends in the Y direction, electrically connects the plurality of drain electrodes 16a and 16c to each other, and electrically connects the plurality of drain electrodes 16a and 16c to the drain bus bar 36. The drain wiring 26b is provided in contact with the drain electrodes 16b and 16d. The drain wiring 26b extends in the Y direction, electrically connects the plurality of drain electrodes 16b and 16d to each other, and electrically connects the plurality of drain electrodes 16b and 16d to the drain bus bar 36.

The gate wiring 24 (first gate wiring) extending in the Y direction is provided on the inactive region 13 between the transistors 35c and 35d. The gate wiring 24 is disposed in the source electrode 12a as viewed from the Y direction. That is, the gate wiring 24 is not disposed outside the source electrode 12a when viewed from the Y direction. The gate wiring 24 is electrically connected to the gate bus bar 34. The gate wiring 24 includes a gate metal layer 24a provided on the substrate 10 and a wiring layer 24b provided on the gate metal layer 24a in contact with the gate metal layer 24a.

A gate wiring 25a (second gate wiring) extending in the X direction is provided between the transistors 35a and 35c and on the inactive region 13 between the transistors 35c. The gate wiring 25a crosses the source wiring 22a in a non-contact manner, and electrically connects the gate wiring 24 to the gate electrodes 14a and 14c. A gate wiring 25b (third gate wiring) extending in the X direction is provided between the transistors 35b and 35d and on the inactive region 13 between the transistors 35d. The gate wiring 25b intersects the source wiring 22b in a non-contact manner, and electrically connects the gate wiring 24 to the gate electrodes 14b and 14d. As a result, the gate electrodes 14a to 14d are electrically connected to the gate bus bar 34 via the gate wirings 24, 25a and 25b. The gate electrodes 14c and 14d of the transistors 35c and 35d closest to the gate bus bar 34 are electrically connected directly to the gate bus bar 34 without passing through the gate wirings 24, 25a and 25b.

A via hole 20a (first via hole) is formed so as to penetrate the substrate 10 and extend from the source electrode 12a on the active region 11a to the source electrode 12a on the inactive region 13. A metal layer 28 is provided on the back surface 52 of the substrate 10. A metal layer 28a is provided on the inner surface of the via hole 20a. As a result, the metal layer 28 (back metal layer) is electrically connected to the source electrode 12a through the via hole 20a. The shape of the via hole 20a in plan view may be oval, ellipse, rounded square, or circular. The source electrodes 12c and 12d are not connected to the via holes 20a.

A source potential (for example, a reference potential such as a ground potential) is supplied from the metal layer 28 to the source electrode 12a through the metal layer 28a in the via hole 20a. Further, the source potential is supplied from the source wiring 22c to the source electrodes 12c and 12d through the source wirings 22a and 22b, respectively. A gate potential (for example, a high-frequency signal and a gate bias voltage) is supplied from the gate bus bar 34 to the gate electrodes 14a to 14d via the gate wirings 24, 25a and 25b. The drain bias voltage is supplied from the drain bus bar 36 to the drain electrodes 16a to 16d through the drain wirings 26a and 26b. The high frequency signals amplified by the transistors 35a to 35d are output from the drain wirings 26a and 26b to the drain bus bar 36.

When the semiconductor device 100 is, for example, a nitride semiconductor device, the substrate 10a is, for example, a silicon carbide (SiC) substrate, a silicon (Si) substrate, a gallium nitride (GaN) substrate, or a sapphire (Al₂O₃) substrate. The semiconductor layer 10b includes a nitride semiconductor layer such as a gallium nitride layer, an aluminum gallium nitride (AlGaN) layer, and/or an indium gallium nitride (InGaN) layer. When the transistors 35a to 35d arc GaN HEMT (Gallium Nitride High Electron Mobility Transistors), the semiconductor layer 10b includes a gallium nitride channel layer provided on the substrate 10a and an aluminum gallium nitride barrier layer provided on the channel layer. When the semiconductor device 100 is, for example, a gallium arsenide (GaAs)-based semiconductor device, the substrate 10a is, for example, a gallium arsenide substrate. The semiconductor layer 10b includes an arsenide semiconductor layer, such as, for example, a gallium arsenide layer, an aluminum gallium arsenide (AlGaAs) layer and/or an indium gallium arsenide (InGaAs) layer. The semiconductor device 100 may be a silicon semiconductor device such as LDMOS (Laterally Diffused Metal Oxide Semiconductor).

The source electrodes 12a, 12c and 12d and the drain electrodes 16a to 16d are metal films, which are, for example, a titanium film and an aluminum film in this order viewed from the substrate 10. The gate electrodes 14a to 14d and the gate metal layer 24a are metal films, which are, for example, a nickel film and a gold film in this order viewed from the substrate 10. The source wirings 22a to 22c, the drain wirings 26a and 26b, the wiring layer 24b, the metal layers 28 and 28a, and the drain bus bar 36 are, for example, gold layers, copper layers, or aluminum layers. The insulating layer 30 provided on the substrate 10 so as to cover the transistors 35a to 35d is an organic insulating layer such as a polyimide layer or a BCB (Benzocyclobutane) layer.

The width of the source electrode 12a in the X direction is, for example, 50 μm to 150 μm. The widths of the source electrodes 12c and 12d in the X direction are, for example, 5 μm to 20 μm. The gate lengths of the gate electrodes 14a to 14d in the X direction are, for example, 0.25 μm to 2 μm. The widths of the drain electrodes 16a to 16d in the X direction are, for example, 5 μm to 150 μm. The width of the gate wiring 24 in the X direction is, for example, 5 μm to 20 μm. The widths of the gate wirings 25a and 25b in the Y direction are, for example, 3 μm to 20 μm. The gate widths of the transistors 35a to 35d in the Y direction are, for example, 100 μm to 400 μm. The width of the via hole 20a in the X direction is, for example, 10 μm to 60 μm.

The widths of the source wirings 22a to 22c and the drain wirings 26a and 26b in the X direction are equal to, slightly smaller than, or larger than the widths of the source electrodes 12a, 12c, and 12d and the drain electrodes 16a to 16d in the X direction, respectively. The thicknesses of the source wirings 22a to 22c and the drain wirings 26a and 26b are, for example, 1 μm to 20 μm.

### FIRST COMPARATIVE EXAMPLE

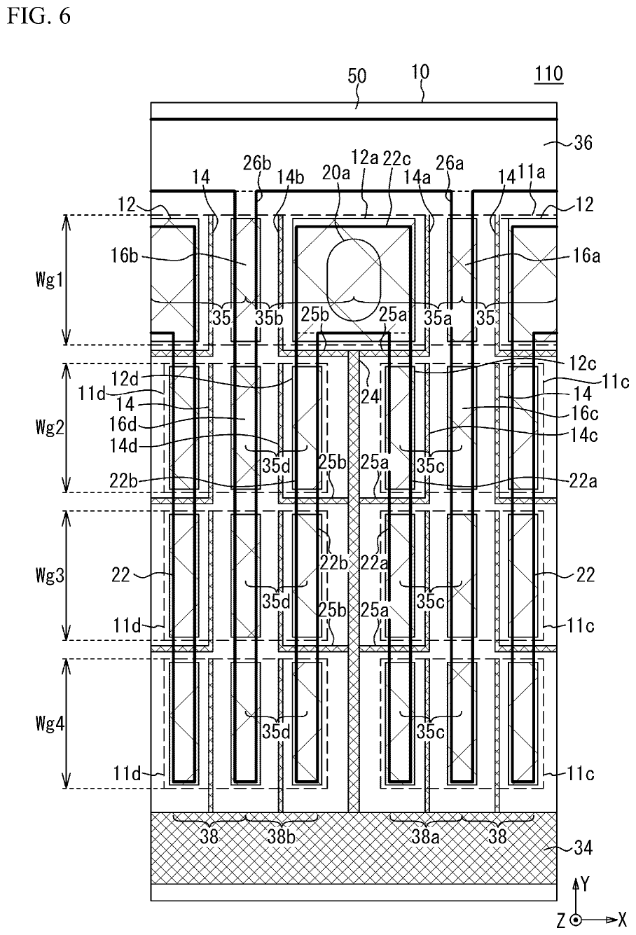

FIG. 6 is a plan view of a semiconductor device according to a first comparative example. As illustrated in FIG. 6, in a semiconductor device 110 of the first comparative example, the + end of the source electrode 12a in the Y direction is positioned substantially at the same position as the + end of the active region 11a in the Y direction when viewed from the X direction. The other configuration is the same as that of the first embodiment.

In the first comparative example, since the gate potential is supplied to the gate electrodes 14a to 14d through the gate wirings 24, 25a and 25b, the gate resistance can be reduced. Since the gate wiring 24 does not overlap the source electrodes 12c and 12d in plan view, the gate-source parasitic capacitance can be reduced as compared with the case of Patent Documents 1 and 2.

In the plurality of transistors 35a to 35d, the widths of the active regions 11a, 11c, and 11d in the Y direction correspond to the gate widths Wg1 to Wg4. When the gate widths Wg1 to Wg4 are different from each other, the operations of the transistors 35a to 35d become uneven, and the high-frequency characteristics of the semiconductor device 110 deteriorate. Therefore, the gate widths Wg1 to Wg4 are made substantially equal.

By reducing the gate width Wg4 from the gate width Wg1, the gate resistance is reduced, and the high-frequency characteristics such as gain can be improved. However, when the gate widths Wg1 to Wg4 are made equal to each other, the width of the source electrode 12a in the Y direction becomes small. This also reduces the width of the via hole 20a in the Y direction. Therefore, the source inductance and the source resistance between the metal layer 28 and the source electrode 12a via the via hole 20a are increased. This results in a decrease in gain. As described above, even if the gain is improved by reducing the gate resistance, the source inductance becomes large, and it is difficult to improve the gain.

### (Further Description of First Embodiment)

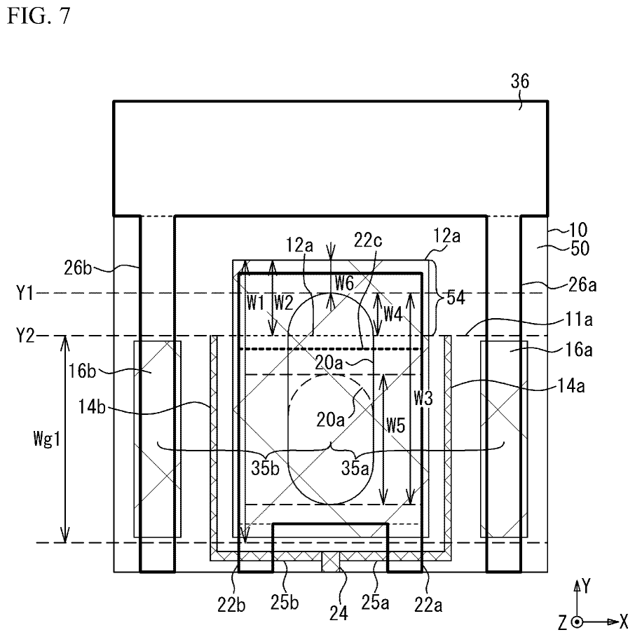

FIG. 7 is an enlarged plan view of the semiconductor device according to the first embodiment, in which the vicinity of the source electrode 12a is enlarged. The source electrode 12a, the source wiring 22c and the via hole 20a (dotted lines) in the first comparative example are illustrated in an overlapped manner on the source electrode 12a, the source wiring 22c and the via hole 20a (solid lines) in the first embodiment.

As illustrated in FIG. 7, in the first comparative example, the widths of the source electrode 12a and the source wiring 22a in the Y direction are substantially equal to the gate width Wg1. In contrast, in the first embodiment, a width W1 of the source electrode 12a and the source wiring 22a in the Y direction is larger than the gate width Wg1 by a width W2. The width W2 corresponds to the distance between the + end of the active region 11a in the Y direction and the + end of the source electrode 12a in the Y direction.

Thus, the width W3 of the via hole 20a in the Y direction of the first embodiment can be made larger than the width W5 of the via hole 20a in the Y direction of the first comparative example by about the width W2. Therefore, in the first embodiment, the end Y1 (first end) of the via hole 20a farther from the transistor 35c is farther from the transistor 35c than the end Y2 (second end) of the active region 11a farther from the transistor 35c in the region where the gate electrode 14a is disposed, as viewed in the X direction. In other words, the via hole 20a extends over both the active region 11a (first active region) and the inactive region 13 in which the substrate 10 is not activated. This makes it possible to increase the area of the via hole 20a as compared with the first comparative example. Therefore, by reducing the gate widths Wg1 through Wg4, the gate resistance can be suppressed and the source inductance can be suppressed. Therefore, it is possible to suppress deterioration of the high-frequency characteristics such as the gain of the semiconductor device.

In view of increasing the area of the via hole 20a, a width W4 between the ends Y1 and Y2 can be 0.1 times or more, and 0.2 times or more, the width W3 of the via hole 20a in the Y direction. From the viewpoint of miniaturization, the width W4 can be set to 0.5 times or less of the width W2.

In view of increasing the area of the via hole 20a, a width W6 between the end of the source electrode 12a and the end of the via hole 20a in the Y direction can be 0.3 times or less, and 0.2 times or less the width WI of the source electrode 12a in the Y direction. The edge and width of the via hole 20a are defined at the point where the via hole 20a is in contact with the main surface 50 of the substrate 10.

From the viewpoint of uniformizing the high-frequency characteristics of the transistors 35a to 35d, a gate width Wg1 of the transistor 35a can be set to 0.9 times or more and 1.1 times or less of a gate width Wg2 of the transistor 35c, and can be set to 0.95 times or more and 1.05 times or less. The gate widths Wg1 to Wg4 can be set to be equal to the manufacturing error.

By providing the transistors 35b and 35d as illustrated in FIGS. 1 to 5, the transistors 35 can be arranged in the X direction and the Y direction.

The source wiring 22a electrically connects the source electrodes 12a and 12c. The gate wiring 25a electrically connects the gate wiring 24 and the gate electrode 14a. This allows the gate electrode 14a and the gate wiring 24 to be electrically connected.

The semiconductor device includes the gate bus bar 34 to which the gate wiring 24 is electrically connected, and the drain bus bar 36 to which the drain wirings 26a and 26b are electrically connected. As a result, the gate potential can be supplied from the gate bus bar 34 to the gate electrodes 14a to 14d, and the drain potential can be supplied from the drain bus bar 36 to the drain electrodes 16a to 16d.

### (First Modification of First Embodiment)

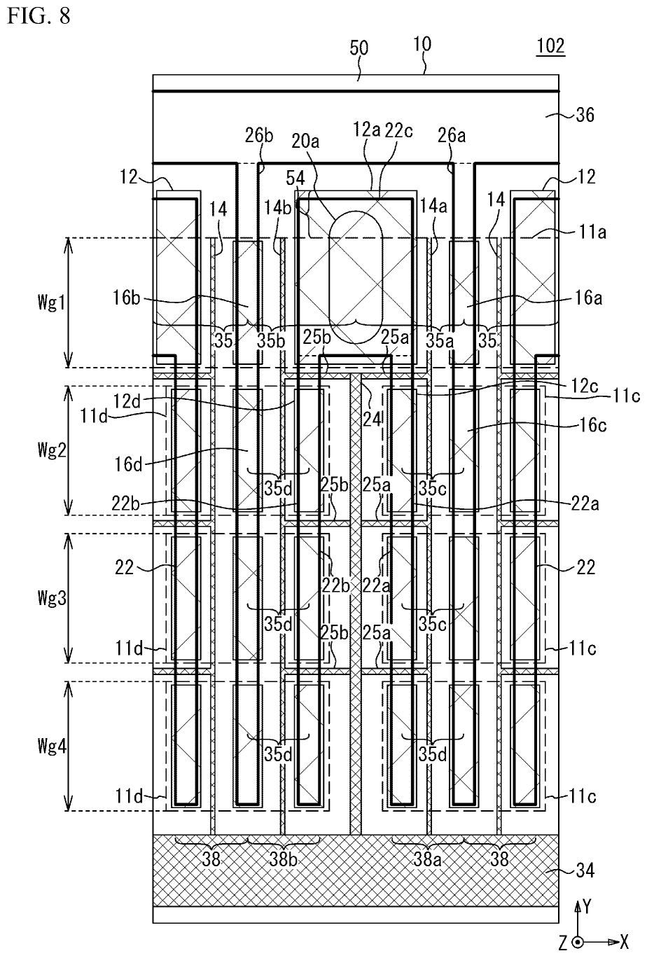

FIG. 8 is a plan view of a semiconductor device according to a first modification of the first embodiment. As illustrated in FIG. 8, in a semiconductor device 102 of the first modification of the first embodiment, the gate electrodes 14 of the transistors 35 of the same transistor group 38 are connected and integrated. The gate electrodes 14a and 14c of the transistor group 38a are connected and integrated. The gate electrodes 14b and 14d of the transistor group 38b are connected and integrated. The other configurations are the same as those of the first embodiment, and the description thereof is omitted.

### SECOND EMBODIMENT

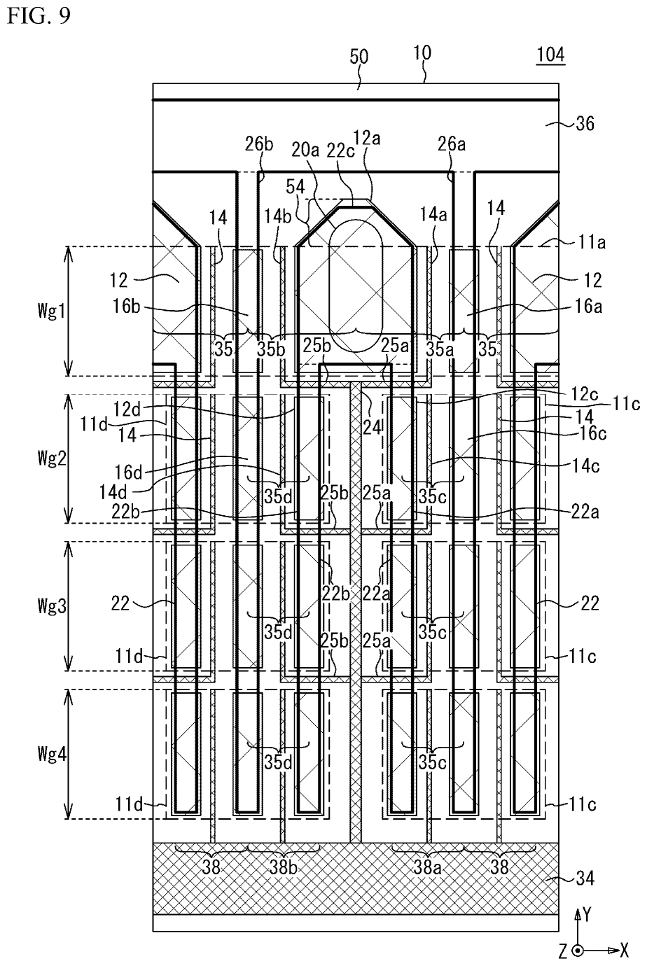

FIG. 9 is a plan view of a semiconductor device according to a second embodiment. As illustrated in FIG. 9, in a semiconductor device 104 of the second embodiment, the corners of the + ends of the source electrode 12a and the source wiring 22c in the Y direction are chamfered. The other configurations are the same as those of the first embodiment, and the description thereof is omitted.

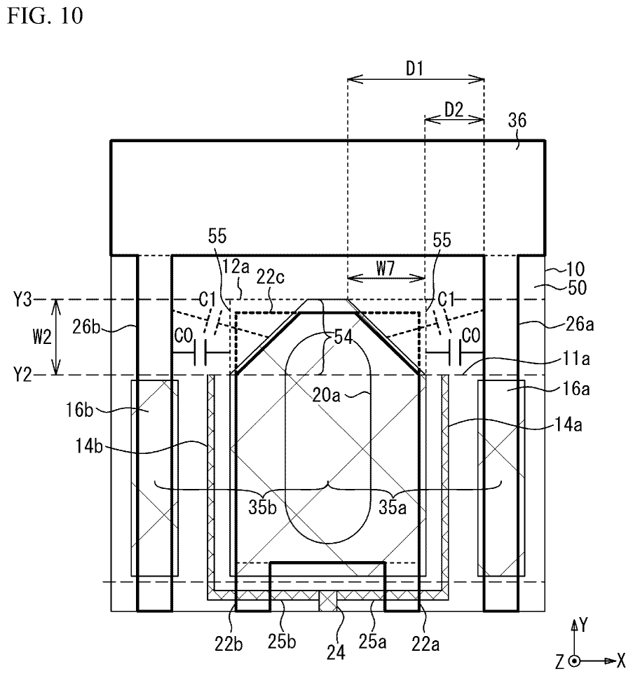

FIG. 10 is an enlarged plan view of the semiconductor device according to the second embodiment, in which the vicinity of the source electrode 12a is enlarged. The source electrode 12a and the source wiring 22c (dotted lines) in the first embodiment are illustrated in a manner superimposed on the source electrode 12a and the source wiring 22c (solid lines) in the second embodiment.

As illustrated in FIG. 10, in both of the first and second embodiments, the via hole 20a is disposed in the source electrode 12a when viewed from the Z direction. This increases the contact area between the metal layer 28a and the source electrode 12a, and can reduce the source inductance and the source resistance. The + end Y3 of the source electrode 12a and the source wiring 22c in the Y direction is closer to the drain bus bar 36 than the + end Y2 of the active region 11a in the Y direction.

In the first embodiment, in the portion 54 closer to the drain bus bar 36 than the active region 11a, the end sides 55 in the X direction in the planar shapes of the source electrode 12a and the source wiring 22c are substantially parallel to the end sides of the drain wirings 26a and 26b in the X direction. Therefore, a parasitic capacitance C0 is generated between the source electrode 12a and the source wiring 22c and the drain wiring 26a. The parasitic capacitance CO becomes a drain-source parasitic capacitance, and the high-frequency characteristics of the semiconductor device deteriorate.

In the second embodiment, D1 is denoted as the distance between the source electrode 12a and the drain wiring 26a at the end Y3 (third end) of the source electrode 12a far from the transistor 35c when viewed in the X direction. D2 is denoted as the distance between the source electrode 12a and the drain wiring 26a at the end Y2 of the active region 11a which is far from the transistor 35c when viewed in the X direction. In this case, the distance D1 is larger than the distance D2. This makes it possible to make the parasitic capacitance C1 generated between the source electrode 12a and the source wiring 22c and the drain wiring 26a smaller than the parasitic capacitance C0 of the first embodiment. Therefore, since the drain-source parasitic capacitance can be suppressed, the deterioration of the high-frequency characteristics of the semiconductor device can be suppressed.

The end Y3 of the source electrode 12a is provided on the inactive region 13. This makes it possible to reduce the parasitic capacitance C1. Therefore, since the drain-source parasitic capacitance can be suppressed, the deterioration of the high-frequency characteristics of the semiconductor device can be suppressed.

A width W7 (that is, the difference between the distances D1 and D2) between the position of the edge 55 in the X direction at the edge Y2 and the position of the edge 55 in the X direction at the edge Y3 can be 0.2 times or more, 0.5 times or more, and 1.0 times or more the width W2 of the edges Y2 and Y3 in the Y direction. This makes it possible to further suppress the parasitic capacitance C1.

If the distance between the source electrode 12a and the drain wiring 26a is increased at the end Y2, the margin between the via hole 20a and the source electrode 12a is reduced. Therefore, the distance between the source electrode 12a and the drain wiring 26a is made larger from the end Y2 toward the end Y3. That is, the edge 55 is directed inward of the source electrode 12a and the source wiring 22c from the edge Y2 toward the edge Y3. This makes it possible to further reduce the parasitic capacitance C1 generated between the source electrode 12a and the source wiring 22c and the drain wiring 26a. Therefore, since the drain-source parasitic capacitance can be suppressed, the deterioration of the high-frequency characteristics of the semiconductor device can be suppressed.

The plane shape of the edge 55 may be a straight line or a curved line. The edge 55 may be a straight line or a curved line that bulges outward from the source electrode 12a and the source wiring 22c. This ensures a margin between the via hole 20a and the source electrode 12a.

### First Modification of Second Embodiment

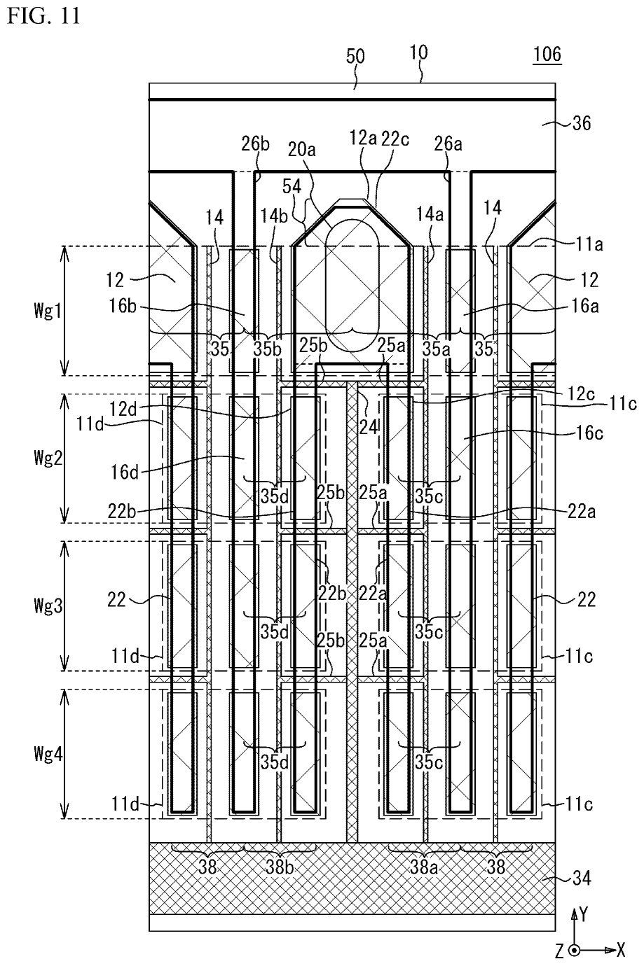

FIG. 11 is a plan view of a semiconductor device according to a first modification of the second embodiment. As illustrated in FIG. 11, in a semiconductor device 106 of the first modification of the second embodiment, the gate electrodes 14 of the transistors 35 of the same transistor group 38 are connected and integrated as in the first modification of the first embodiment. The gate electrodes 14a and 14c of the transistor group 38a are connected and integrated. The gate electrodes 14b and 14d of the transistor group 38b are connected and integrated. The other configurations are the same as those of the second embodiment, and the description thereof is omitted.

In the first modification of the first embodiment and the first modification of the second embodiment, the gate electrodes 14a and 14c are connected between the transistors 35a and 35c, and the gate electrodes 14b and 14d are connected between the transistors 35b and 35d. As a result, gate potentials are supplied to the gate electrodes 14c and 14d from the + and − ends in the Y direction. Therefore, the gate resistance of the transistors 35c and 35d can be further suppressed. In addition, the gate width Wg4 can be increased from the gate width Wg2 of the transistors 35c and 35d.

However, in the transistors 35c and 35d, the high-frequency signal is input from the − end in the Y direction of the gate electrodes 14c and 14d. When the high frequency signals are input to the gate electrodes 14c and 14d from both ends of the + and − ends in the Y direction of the gate electrodes 14c and 14d, the high frequency characteristics of the transistors 35c and 35d are deteriorated due to the phase difference or the like.

In the first and second embodiments, the gate electrodes 14a and 14c are separated from each other between the transistors 35a and 35c, and the gate electrodes 14b and 14d are separated from each other between the transistors 35b and 35d. This makes it possible to suppress deterioration of the high-frequency characteristics of the transistors 35c and 35d.

Although the first and second embodiments and the modification thereof have described the examples in which four transistor groups 38a and 38b are arranged in the X direction, three or more transistor groups 38a and 38b may be arranged in the X direction. The transistors 35c and 35d may be arranged in the Y direction one or more than one. The source wirings between which the drain wiring 26 is interposed in the X direction may be connected between the drain wiring and the gate bus bar 34.

In the first and second embodiments and the modification thereof, the plurality of drain electrodes 16 (for example, drain electrodes 16a and 16c) electrically connected to the same drain wiring 26 (for example, drain wiring 26a) are separated from each other in the inactive region 13. The plurality of drain electrodes 16 (for example, drain electrodes 16a and 16c) to which the drain wiring 26 (for example, drain wiring 26a) is electrically connected may be connected to each other in the inactive region 13. In the transistor 35 (for example, the transistor 35a), the source electrode 12 and the source wiring 22 (for example, the source electrode 12a and the source wiring 22c) can be collectively referred to as a source electrode, and the drain electrode 16 and the drain wiring 26 (for example, the drain electrode 16a and the drain wiring 26a) can be collectively referred to as a drain electrode.

### THIRD EMBODIMENT

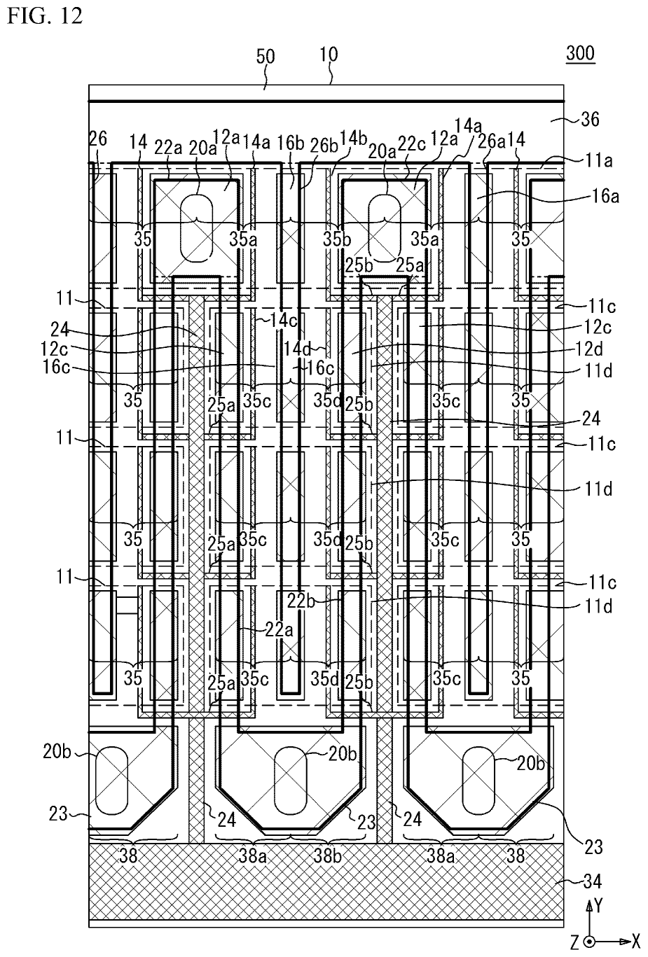

FIG. 12 is a plan view of a semiconductor device according to a third embodiment. The same configuration as that of the first or second embodiment will not be described. As illustrated in FIG. 12, in a semiconductor device 300 of the third embodiment, for example, three transistors 35c are arranged in the Y direction. For example, three transistors 35d are arranged in the Y direction. In the X direction, the transistors 35c and 35d are alternately arranged. In FIG. 12, the transistors 35c are provided on both sides of the transistor 35d.

The gate electrode 14 does not extend to the gate bus bar 34. The gate wiring 24 extends to the gate bus bar 34 and is connected to the gate bus bar 34.

A source connection wiring 23 is provided at the opposite side of the transistors 35c and 35d with respect to the transistors 35a and 35b. The source connection wiring 23 electrically connects the source wiring 22a to the source wiring 22b. The gate wirings 24 are provided on both sides of the source connection wiring 23 in the X direction. The corners of the-ends of the source connection wiring 23 in the Y direction are chamfered. A via hole 20b (second via hole) is provided at a position overlapping the source connection wiring 23 and penetrates the substrate 10. The source connection wiring 23 is connected to the metal layer 28 on the back surface 52 of the substrate 10 through the via hole 20b.

According to the third embodiment, the source connection wiring 23 is connected to the metal layer 28 through the via hole 20b and short-circuited. This can reduce the source inductance. The deterioration of the high-frequency characteristics can be suppressed.

The corners of the source connection wiring 23 are chamfered. Therefore, the distance between the source connection wiring 23 and the gate wiring 24 changes along the Y direction. A distance between the source connection wiring 23 and the gate wiring 24 decreases in accordance with a position closer to the transistors 35c and 35d in the Y direction. The distance between the source connection wiring 23 and the gate wiring 24 increases in accordance with a position farther from the transistors 35c and 35d in the Y direction. This makes it possible to suppress the gate-source parasitic capacitance and suppress the deterioration of the high-frequency characteristics.

### Modification of Third Embodiment

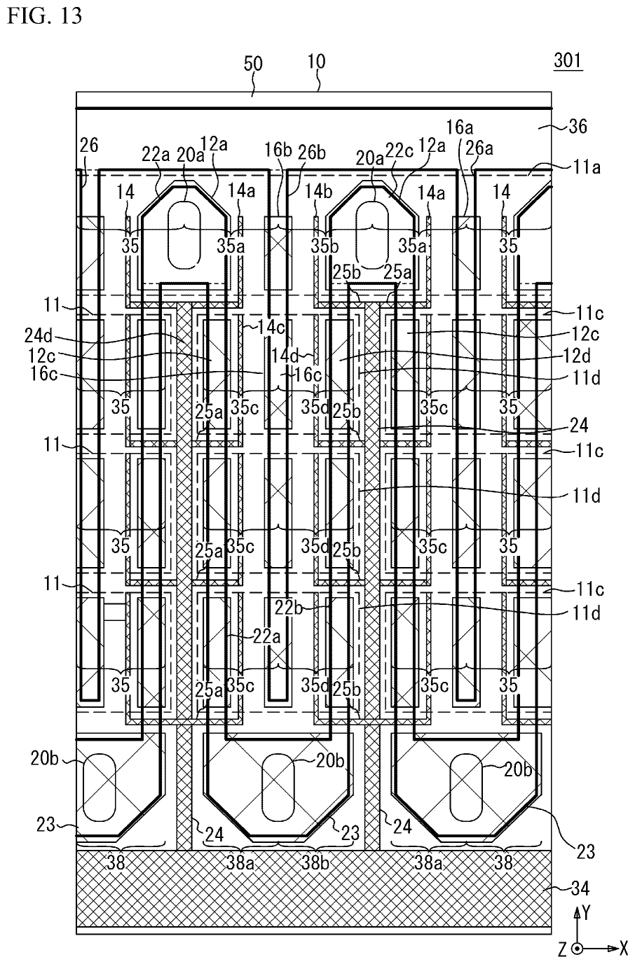

FIG. 13 is a plan view of a semiconductor device 301 according to a modification of the third embodiment. The same configuration as that of the third embodiment will not be described. The corners of the + ends of the source electrode 12 and the source wiring 22 in the Y direction are chamfered.

As described in FIG. 10, the distance D1 between the drain electrode 26, and the source electrode 12 and the source wiring 22 is larger than the distance D2. In addition, the distance between the source connection wiring 23 and the gate wiring 24 increases in accordance with a position farther from the transistors 35c and 35d in the Y direction. This makes it possible to suppress the drain-source parasitic capacitance and the gate-source parasitic capacitance and suppress the deterioration of the high-frequency characteristics.

The embodiments disclosed herein are to be considered as illustrative in all respects and not restrictive. The scope of the present disclosure is not in the sense set forth above, but is indicated by the claims, and is intended to include all modifications within the meaning and scope of the claims and equivalents.

What is claimed is:

1. A semiconductor device comprising:
a substrate having a main surface and a back surface facing the main surface;
a first transistor provided on the main surface of an active region provided on the substrate, the first transistor having a first source electrode, a first drain electrode, and a first gate electrode interposed between the first source electrode and the first drain electrode in a first direction;
a second transistor provided on the main surface, the second transistor having a second source electrode disposed in the first source electrode and electrically connected to the first source electrode when viewed from a second direction intersecting the first direction, a second drain electrode electrically connected to the first drain electrode, and a second gate electrode interposed between the second source electrode and the second drain electrode in the first direction;
a first gate wiring provided on the main surface, disposed in the first source electrode when viewed from the second direction, and electrically connected to the first gate electrode, the second source electrode being interposed between the first gate wiring and the second gate electrode; and
a back metal layer provided on the back surface and electrically connected to the first source electrode through a first via hole penetrating the substrate,
wherein a first end of the first via hole which is farther from the second transistor is farther from the second transistor than a second end of the active region which is farther from the second transistor in a region where the first gate electrode is disposed, as viewed from the first direction.

2. The semiconductor device according to claim 1, wherein the first via hole is formed in the first source electrode when viewed in a thickness direction of the substrate.

3. The semiconductor device according to claim 1, further comprising:
a drain bus bar provided on the main surface, the first transistor being interposed between the second transistor and the drain bus bar; and
a drain wiring connecting the first drain electrode and the second drain electrode to the drain bus bar,
wherein a distance between the first source electrode and the drain wiring at a third end of the first source electrode farther from the second transistor when viewed from the first direction is larger than a distance between the first source electrode and the drain wiring at the second end.

4. The semiconductor device according to claim 3, wherein the third end of the first source electrode is provided on an inactive region provided on the substrate.

5. The semiconductor device according to claim 3, wherein a distance between the first source electrode and the drain wiring increases from the second end toward the third end.

6. The semiconductor device according to claim 1, wherein a gate width of the first transistor is 0.9 times or more and 1.1 times or less of a gate width of the second transistor.

7. The semiconductor device according to claim 1, wherein the first gate electrode and the second gate electrode are separated from each other between the first transistor and the second transistor.

8. The semiconductor device according to claim 1, wherein the first gate electrode and the second gate electrode are connected between the first transistor and the second transistor.

9. The semiconductor device according to claim 1, further comprising:
a third transistor provided on the main surface, having the first source electrode, a third drain electrode and a third gate electrode, the first source electrode being interposed between the first source electrode and the first gate electrode, the third gate electrode being interposed between the first source electrode and the third drain electrode in the first direction; and
a fourth transistor provided on the main surface, having a third source electrode, a fourth drain electrode and a fourth gate electrode, the first gate wiring being interposed between the second source electrode and the third source electrode, the third source electrode being disposed in the first source electrode viewed from the second direction, the third source electrode being interposed between the first gate wiring and the fourth drain electrode, the second gate electrode being interposed between the third source electrode and the fourth drain electrode in the first direction.

10. The semiconductor device according to claim 1, further comprising:
a source wiring provided on the main surface and electrically connecting the first source electrode and the second source electrode; and
a second gate wiring provided on the main surface and electrically connecting the first gate wiring and the first gate electrode.

11. The semiconductor device according to claim 1, further comprising:
a gate bus bar provided on the main surface and connected to the second gate electrode and the first gate wiring; and
a drain bus bar provided on the main surface and electrically connected to the first drain electrode and the second drain electrode, the first transistor and the second transistor being interposed between the gate bus bar and the drain bus bar.

12. The semiconductor device according to claim 9, further comprising:
a source connection wiring provided on the main surface at an opposite side of the second transistor and the fourth transistor with respect to the first transistor and the third transistor;
wherein the source connection wiring electrically connects the second source electrode of the second transistor to the third source electrode of the fourth transistor,
the source connection wiring is electrically connected to the back metal layer through a second via hole penetrating the substrate, and
a distance between the source connection wiring and the first gate wiring increases in accordance with a position farther from the second transistor and the fourth transistor in the second direction.
